(19) United States
(12) Patent Application Publication
(10) Pub. No.: US 2023/0363160 A1
(43) Pub. Date: Nov. 9, 2023

(54) FLASH MEMORY DEVICE, SEMICONDUCTOR DEVICE, AND METHOD OF FABRICATING THE SAME

(71) Applicant: MACRONIX International Co., Ltd., Hsinchu (TW)

(72) Inventors: Meng-Yen Wu, Taichung City (TW); Pi-Shan Tseng, Tainan City (TW)

(73) Assignee: MACRONIX International Co., Ltd., Hsinchu (TW)

(21) Appl. No.: 17/737,771

(22) Filed: May 5, 2022

(51) Int. Cl. H01L 27/11582; H01L 27/11519; H01L 27/11556; H01L 27/11565; H01L 23/528; H01L 23/522; H01L 23/04

(52) U.S. Cl. CPC H01L 27/11582; H01L 27/11519; H01L 27/11556; H01L 27/11565; H01L 23/5283; H01L 23/5226; H01L 23/04

(57) ABSTRACT

A memory device may be applicated in a 3D AND flash memory device. The memory device includes a dielectric substrate, a plurality of memory cells, a slit structure, and a middle section of a seal ring. The gate composite stack structure disposed on the dielectric substrate in a first region and a second region of the dielectric substrate. The plurality of memory cells disposed in the composite stack structure. The slit structure extends through the composite stack structure in first region. The composite stack structure is divided into a plurality of blocks. The middle section of a seal ring extends through the composite stack structure in the second region. The middle section of the seal ring includes a body part extending through the composite stack structure in the second region and a liner layer located between the body part and the composite stack structure.

### BACKGROUND

### Technical Field

The embodiment of the disclosure relates to a semiconductor device and a method of fabricating the same, and particularly to a memory device and a method of fabricating the same.

### Description of Related Art

Since a non-volatile memory has the advantage that stored data does not disappear at power-off, it becomes a widely used memory for a personal computer or other electronics equipment. Currently, the 3D memory commonly used in the industry includes a NOR memory and a NAND memory. In addition, another 3D memory is an AND memory, which may be applied to a multi-dimensional memory array with high integration and high area utilization, and has an advantage of a fast operation speed. Therefore, the development of a 3D AND flash memory device has gradually become the current trend.

### SUMMARY

The embodiment of disclosure provides a 3 memory device that may effectively isolate the stack structure of two adjacent tile regions, so that the leakage path between the substrate and the grounded conductive layer may be reduced or avoided to increase the current Ioff and reduce the impact on the memory cell operation.

The embodiment of disclosure provides a manufacturing method of a memory device, which may form a seal ring in the periphery of a tile region while forming a memory device. Therefore, the method may be integrated with the existing process without increasing the process steps.

A memory device according to an embodiment of the disclosure includes a dielectric substrate, a composite stack structure, a plurality of memory cells, a slit structure, and a middle section of a seal ring. The dielectric substrate has a first region and a second region surrounding the first region. The composite stack structure disposed on the dielectric substrate in the first region and the second region. The plurality of memory cells disposed in the composite stack structure. The slit structure extends through the composite stack structure in first region. The composite stack structure is divided into a plurality of blocks by the slit structure. The middle section of the seal ring extends through the composite stack structure in the second region. The middle section of the seal ring includes a body part and a liner layer. The body part extends through the composite stack structure in the second region, and the liner layer is located between the body part and the composite stack structure.

A method of fabricating a memory device according to an embodiment of the disclosure includes the following steps. A dielectric substrate is provided. The dielectric substrate has a first region and a second region surrounding the first region. A stack structure is formed on the dielectric substrate in the first region and the second region. The stack structure includes a plurality of insulating layers and a plurality of intermediate layers alternately stacked each other. A slit structure and a middle section of a seal ring are formed. The slit structure is located in the stack structure in the first region, and the middle section of the seal ring is located in the stack structure in the second region.

A semiconductor device according to an embodiment of the disclosure includes a composite stack structure, and a seal ring. The composite stack structure is located on a dielectric substrate. The composite stack structure includes a plurality of conductive layers and a plurality of insulating layers stacked alternately. A middle section of the seal ring extends through the composite stack structure in the second region and is electrically isolated from the plurality of conductive layers. An upper section of the seal ring is located above and electrically connected to the middle section. A lower section of the seal ring located is below and electrically connected to the middle section.

Based on the above, in the three-dimensional flash memory of an embodiment of the disclosure, the seal ring of an embodiment of the disclosure may pass through the ground conductor layer upward from the surface of the substrate, and be continuously extended to the top surface of the upper interconnect structure. Therefore, the three-dimensional flash memory of an embodiment of the disclosure may effectively isolate the stacked structure of two adjacent tile regions to reduce or avoid the leakage path between the substrate and the ground conductor layer and increase the off current Ioff, and reduce impact on memory cell operations.

The manufacturing method of a three-dimensional flash memory of an embodiment of the disclosure may form a seal ring at the periphery of the block region while forming a memory element, and therefore the method may be integrated with the existing process without increasing the process steps.

### BRIEF DESCRIPTION OF THE DRAWINGS

FIG. 1A shows a circuit diagram of a 3D AND flash memory array in accordance with some embodiments.

FIG. 1B shows a partial three-dimensional view of the memory array of the portion of FIG. 1A.

FIG. 1C and FIG. 1D show cross-sectional views of the line II′ of FIG. 1B.

FIG. 1E shows a top view of the cut line II-II′ of FIGS. 1B, 1C, and 1D.

FIG. 1F shows a top view of the 3D AND flash memory.

FIG. 2A to FIG. 2J illustrate top views of a manufacturing flow of a 3D AND flash memory according to some embodiments.

FIG. 3A to FIG. 3J show cross-sectional views of line III-III′ of FIG. 2A to 2J.

FIG. 4A to FIG. 4J show cross-sectional views of line IV-IV′ of FIG. 2A to 2J.

FIG. 5 shows a top view of a 3D AND flash memory according to other embodiments.

FIG. 6 shows a cross-sectional view along line V-V′ of FIG. 5.

FIG. 7 shows a cross-sectional view along line VI-VI′ of FIG. 5.

### DESCRIPTION OF THE EMBODIMENTS

A sealing ring according to an embodiment of the disclosure is arranged to extend through the composite stack structure. The composite stack structure may be used to form various semiconductor devices, such as memory devices. For brevity, a 3D AND flash memory is described below, however, the present disclosure is not limited thereto.

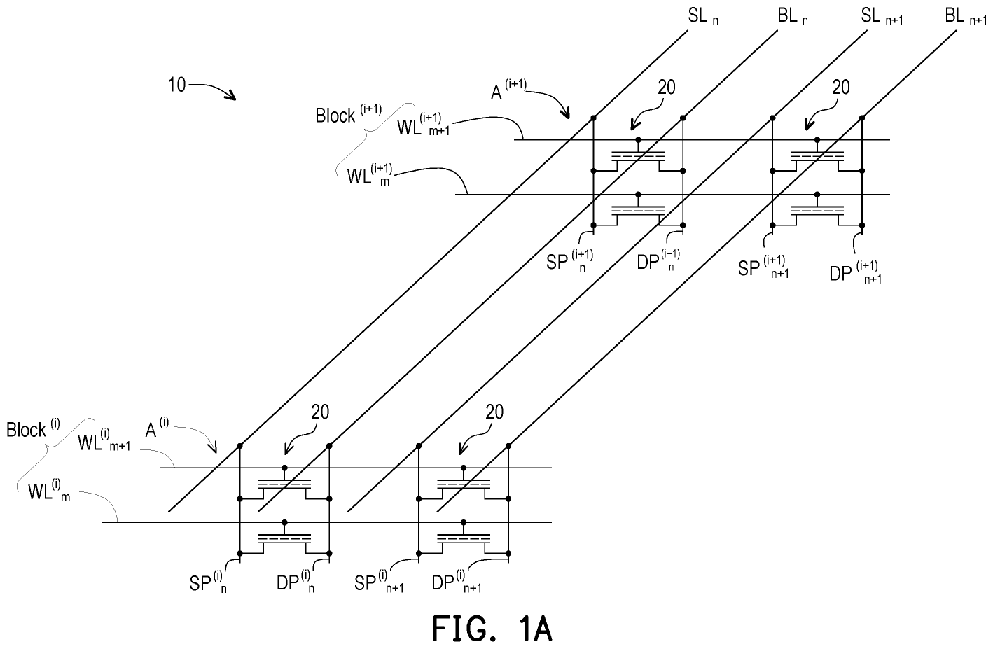

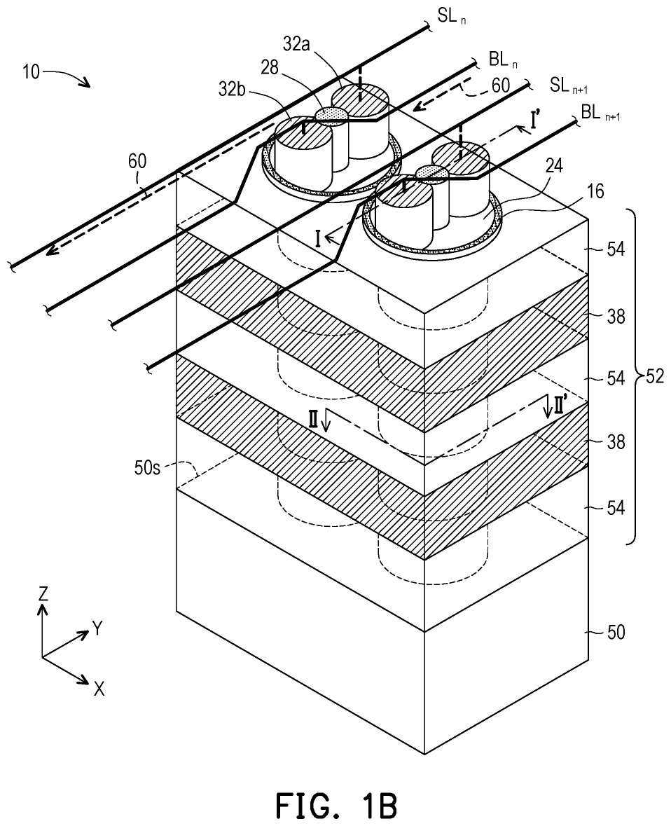

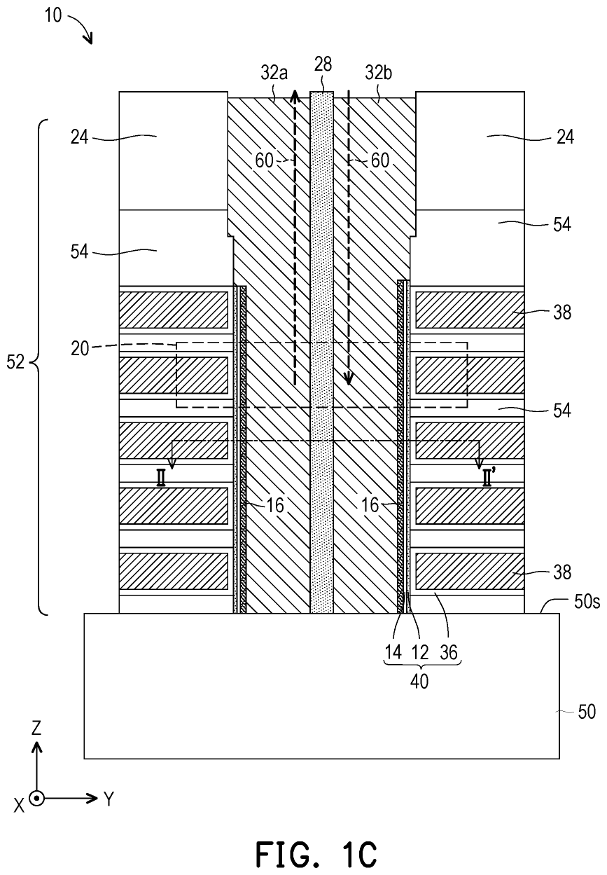

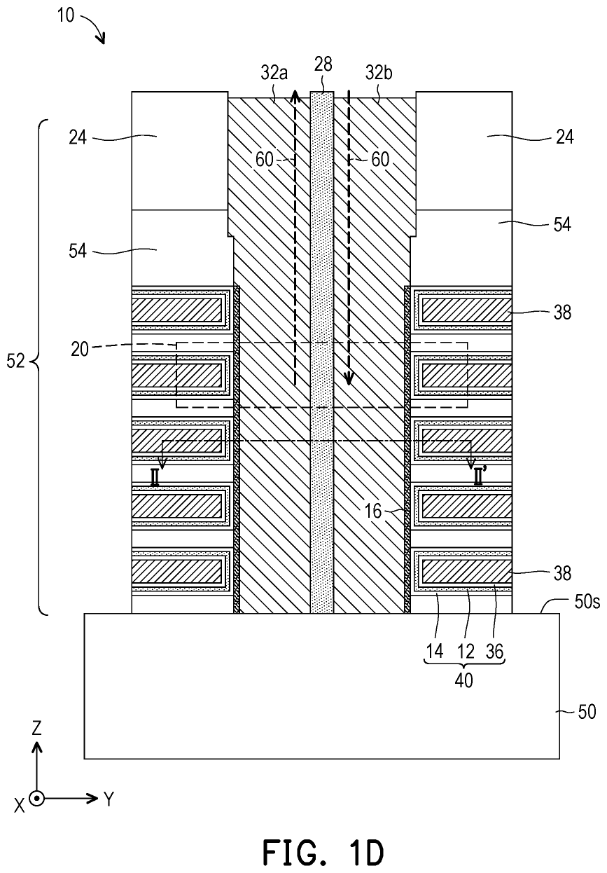

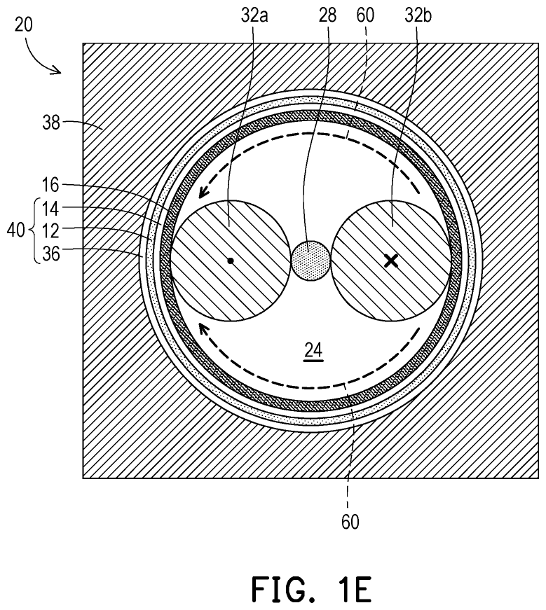

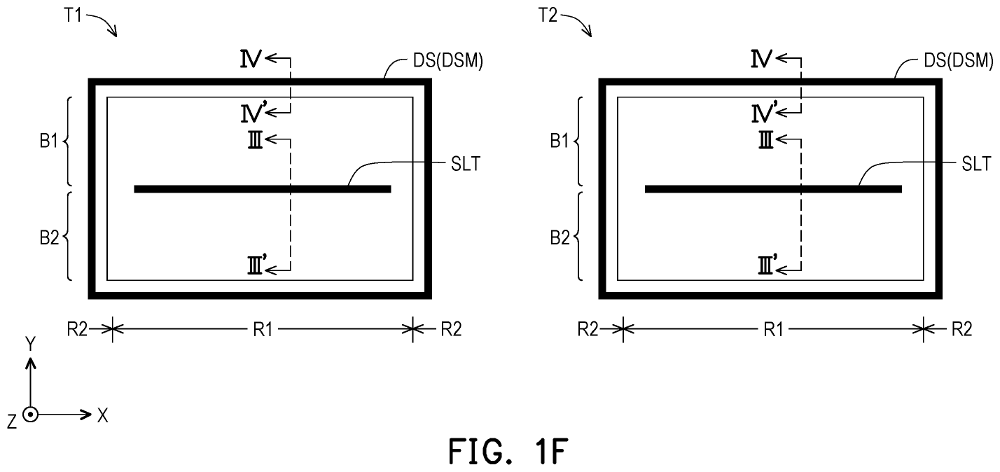

FIG. 1A shows a circuit diagram of a 3D AND flash memory array according to some embodiments in according to the present disclosure. FIG. 1B shows a partial simplified perspective view of the memory array in FIG. 1A. FIG. 1C and FIG. 1D show cross-sectional views taken along line I-I′ of FIG. 1B. FIG. 1E shows atop view of line II-II′ of FIG. 1B, FIG. 1C and FIG. 1D.

FIG. 1A shows a schematic view of two blocks BLOCK⁽ⁱ⁾ and BLOCK⁽ⁱ⁺¹⁾ of a vertical AND memory array 10 arranged in rows and columns. The block BLOCK⁽ⁱ⁾ includes a memory array A⁽ⁱ⁾. A row (e.g., an (m+1)th row) of the memory array A⁽ⁱ⁾ is a set of AND memory cells 20 having a common word line (e.g., WL⁽ⁱ⁾ₘ₊₁). The AND memory cells 20 of the memory array A⁽ⁱ⁾ in each row (e.g., the (m+1)th row) correspond to a common word line (e.g., WL⁽ⁱ⁾ₘ₊₁) and are coupled to different source pillars (e.g., SP⁽ⁱ⁾ and SP⁽ⁱ⁾ₙ₊₁) and drain pillars (e.g., DP⁽ⁱ⁾n and DP⁽ⁱ⁾ₙ₊₁), so that the AND memory cells 20 are logically arranged in a row along the common word line (e.g., WL⁽ⁱ⁾ₘ₊₁).

A column (e.g., an n^{th} column) of the memory array A⁽ⁱ⁾ is a set of AND memory cells 20 having a common source pillar (e.g., SP⁽ⁱ⁾ₙ) and a common drain pillar (e.g., DP⁽ⁱ⁾ₙ). The AND memory cells 20 of the memory array A⁽ⁱ⁾ in each column (e.g., the n^{th} column) correspond to different word lines (e.g., WL⁽ⁱ⁾ₘ₊₁ and WL⁽ⁱ⁾ₘ) and are coupled to a common source pillar (e.g., SP⁽ⁱ⁾ₙ) and a common drain pillar (e.g., DP⁽ⁱ⁾ₙ). Hence, the AND memory cells 20 of the memory array A⁽ⁱ⁾ are logically arranged in a column along the common source pillar (e.g., SP⁽ⁱ⁾ₙ) and the common drain pillar (e.g., DP⁽ⁱ⁾ₙ). In the physical layout, according to the fabrication method as applied, the columns or rows may be twisted and arranged in a honeycomb pattern or other patterns for high density or other reasons.

In FIG. 1A, in the block BLOCK⁽ⁱ⁾, the AND memory cells 20 in the n^{th} column of the memory array A⁽ⁱ⁾ share a common source pillar (e.g., SP⁽ⁱ⁾ₙ) and a common drain pillar (e.g., DP⁽ⁱ⁾ₙ). The AND memory cells 20 in an (n+1)th column share a common source pillar (e.g., SP⁽ⁱ⁾ₙ₊₁) and a common drain pillar (e.g., DP⁽ⁱ⁾ₙ₊₁).

The common source pillar (e.g., SP⁽ⁱ⁾ₙ) is coupled to a common source line (e.g., SLₙ) and the common drain pillar (e.g., DP⁽ⁱ⁾ₙ) is coupled to a common bit line (e.g., BLₙ). The common source pillar (e.g., SP⁽ⁱ⁾ₙ₊₁) is coupled to a common source line (e.g., SLₙ₊₁) and the common drain pillar (e.g., DP⁽ⁱ⁾ₙ₊₁) is coupled to a common bit line (e.g., BLₙ₊₁).

Likewise, the block BLOCK⁽ⁱ⁺¹⁾ includes a memory array A⁽ⁱ⁺¹⁾, which is similar to the memory array A⁽ⁱ⁾ in the block BLOCK⁽ⁱ⁾. A row (e.g., an (m+1)th row) of the memory array A⁽ⁱ⁺¹⁾ is a set of AND memory cells 20 having a common word line (e.g., WL⁽ⁱ⁺¹⁾ₘ₊₁). The AND memory cells 20 of the memory array A⁽ⁱ⁺¹⁾ in each row (e.g., the (m+1)th row) correspond to a common word line (e.g., WL⁽ⁱ⁺¹⁾ₘ₊₁) and are coupled to different source pillars (e.g., SP⁽ⁱ⁺¹⁾ₙ and SP⁽ⁱ⁺¹⁾ₙ₊₁) and drain pillars (e.g., DP⁽ⁱ⁺¹⁾ₙ and DP⁽ⁱ⁺¹⁾ₙ₊₁). A column (e.g., an n^{th} column) of the memory array A⁽ⁱ⁺¹⁾ is a set of AND memory cells 20 having a common source pillar (e.g., SP⁽ⁱ⁺¹⁾ₙ) and a common drain pillar (e.g., DP⁽ⁱ⁺¹⁾ₙ). The AND memory cells 20 are integrated and connected in parallel, and thus may be also referred to as a memory string. The AND memory cells 20 of the memory array A⁽ⁱ⁺¹⁾ in each column (e.g., the n^{th} column) correspond to different word lines (e.g., WL⁽ⁱ⁺¹⁾ₘ₊₁ and WL⁽ⁱ⁺¹⁾ₘ) and are coupled to a common source pillar (e.g., SP⁽ⁱ⁺¹⁾ₙ) and a common drain pillar (e.g., DP⁽ⁱ⁺¹⁾ₙ). Hence, the AND memory cells 20 of the memory array A⁽ⁱ⁺¹⁾ are logically arranged in a column along the common source pillar (e.g., SP⁽ⁱ⁺¹⁾ₙ) and the common drain pillar (e.g., DP⁽ⁱ⁺¹⁾ₙ).

The block BLOCK⁽ⁱ⁺¹⁾ and the block BLOCK⁽ⁱ⁾ share source lines (e.g., SLₙ and SLₙ₊₁) and bit lines (e.g., BLₙ and BLₙ₊₁). Therefore, the source line SLₙ and the bit line BLₙ are coupled to the n^{th} column of AND memory cells 20 in the AND memory array A⁽ⁱ⁾ of the block BLOCK⁽ⁱ⁾, and are coupled to the n^{th} column of AND memory cells 20 in the AND memory array A⁽ⁱ⁺¹⁾ of the block BLOCK⁽ⁱ⁺¹⁾. Similarly, the source line SLₙ₊₁ and the bit line BLₙ₊₁ are coupled to the (n+1)th column of AND memory cells 20 in the AND memory array A⁽ⁱ⁾ of the block BLOCK⁽ⁱ⁾, and are coupled to the (n+1)th column of AND memory cells 20 in the AND memory array A⁽ⁱ⁺¹⁾ of the block BLOCK⁽ⁱ⁺¹⁾.

Referring to FIG. 1B to FIG. 1D, the memory array 10 may be disposed over an interconnect structure of a semiconductor die, for example, being disposed on one or more active devices (e.g., transistors) formed on a semiconductor substrate. Therefore, the dielectric substrate 50 is, for example, a dielectric layer (e.g., a silicon oxide layer) over a conductive interconnect structure formed on a silicon substrate. The memory array 10 may include a gate stack structure GSK, a plurality of channel pillars 16, a plurality of first conductive pillars (also referred to as source pillars) 32a, a plurality of second conductive pillars (also referred to as drain pillars) 32b, and a plurality of charge storage structures 40.

Referring to FIG. 1B, the gate stack structure GSK is formed on the dielectric substrate 50 in the array region (not shown) and the staircase region (not shown). The gate stack structure GSK includes a plurality of gate layers (also referred to as word lines) 38 and a plurality of insulating layer 54 vertically stacked on a surface 50s of the dielectric substrate 50. In a direction Z, the gate layers 38 are electrically isolated from each other by the insulating layer 54 disposed therebetween. The gate layers 38 extend in a direction parallel to the surface 50s of the dielectric substrate 50. The gate layers 38 in the staircase region may have a staircase structure (not shown). Therefore, a lower gate layer 38 is longer than an upper gate layer 38, and the end of the lower gate layer 38 extends laterally beyond the end of the upper gate layer 38. A contact (not shown) for connecting the gate layer 38 may land on the end of the gate layer 38 to connect the gate layers 38 respectively to conductive lines.

Referring to FIG. 1B to FIG. 1D, the memory array 10 further includes a plurality of channel pillars 16 along in a direction (i.e., the direction Z) perpendicular to the surface of the gate layer 38. In some embodiments, the channel pillar 16 extends continuously through the stack structure 52 in the first region R1. In other some embodiments, the channel pillar 16 extends discontinuously through the stack structure 52 in the first region R1. In some embodiments, each of the channel pillars 16 has an annular shape from a top view. A material of the channel pillars includes a semiconductor material, such as undoped polysilicon.

Referring to FIG. 1B to FIG. 1D, the memory array 10 further includes an insulating pillar 28, a plurality of first conductive pillars 32a, and a plurality of second conductive pillars 32b. In this example, the first conductive pillars 32a serve as source pillars. The second conductive pillars 32b serve as drain pillars. The first conductive pillar 32a, the second conductive pillar 32b and the insulating pillar 28 are each extend in a direction (i.e., the direction Z) perpendicular to the surface of the gate layer 38. The first conductive pillar 32a and the second conductive pillar 32b are separated from each other by the insulating pillar 28. The first conductive pillar 32a and the second conductive pillar 32b are electrically connected to the channel pillars 16. The first conductive pillar 32a and the second conductive pillar 32b further extends through a conductive layer 53 located between the gate stack structure GSK and the dielectric substrate 52, and land on a stop layer 52 under the conductive layer 53. The first conductive pillar 32a and the second conductive pillar 32b include doped polysilicon or metal materials. The insulating pillar 28 is, for example, silicon nitride.

Referring to FIG. 1C and FIG. 1D, the charge storage structures 40 are disposed between the channel pillars 16 and the gate layers 38. Each of the charge storage structure 40 may include a tunneling layer (or referred to as a bandgap engineered tunneling oxide layer) 14, a charge storage layer 12, and a blocking layer 36. The charge storage layer 12 is located between the tunneling layer 14 and the blocking layer 36. In some embodiments, the tunneling layer 14 and the blocking layer 36 include silicon oxide. The charge storage layer 12 includes silicon nitride or other materials capable of trapping charges. In some embodiments, as shown in FIG. 1C, a portion (the tunneling layer 14 and the charge storage layer 12) of the charge storage structure 40 continuously extends in a direction (i.e., the direction Z) perpendicular to the gate layer 38, and the other portion (the blocking layer 36) of the charge storage structure 40 surrounds the gate layer 38. In other embodiments, as shown in FIG. 1D, the charge storage structure 40 (the tunneling layer 14, the charge storage layer 12, and the blocking layer 36) surrounds the gate layer 38.

Referring to FIG. 1E, the charge storage structure 40, the channel pillar 16, the source pillar 32a, and the drain pillar 32b are surrounded by the gate layer 38, and a memory cell 20 is defined. According to different operation methods, a 1-bit operation or a 2-bit operation may be performed on the memory cell 20. For example, when a voltage is applied to the source pillar 32a and the drain pillar 32b, since the source pillar 32a and the drain pillar 32b are connected to the channel pillar 16, electrons may be transferred along the channel pillar 16 and stored in the entire charge storage structure 40. Accordingly, a 1-bit operation may be performed on the memory cell 20. In addition, for an operation involving Fowler-Nordheim tunneling, electrons or holes may be trapped in the charge storage structure 40 between the source pillar 32a and the drain pillar 32b. For an operation involving source side injection, channel-hot-electron injection, or band-to-band tunneling hot carrier injection, electrons or holes may be locally trapped in the charge storage structure 40 adjacent to one of the source pillar 32a and the drain pillar 32b. Accordingly, a single level cell (SLC, 1 bit) or multi-level cell (MLC, greater than or equal to 2 bits) operation may be performed on the memory cell 20.

Referring to FIG. 1A and FIG. 1B, during operation, a voltage is applied to a selected word line (gate layer) 38; for example, when a voltage higher than a corresponding threshold voltage (Vth) of the corresponding memory cell 20 is applied, the channel pillar 16 intersecting the selected word line 38 is turned on to allow a current to enter the drain pillar 32b from the bit line BLₙ or BLₙ₊₁ (shown in FIG. 1B), flow to the source pillar 32a via the turned-on channel region (e.g., in a direction indicated by arrow 60), and finally flow to the source line SLₙ or SLₙ₊₁ (shown in FIG. 1B).

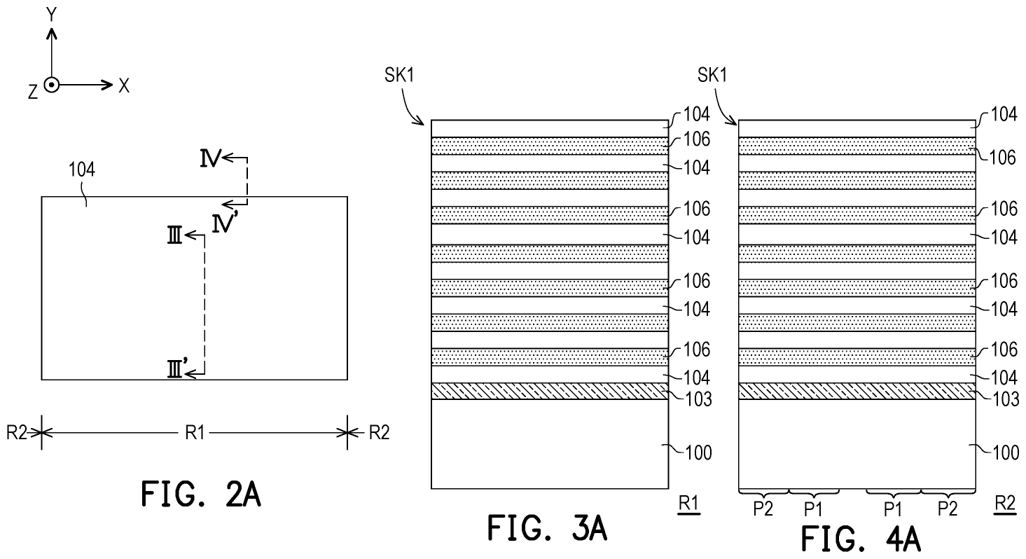

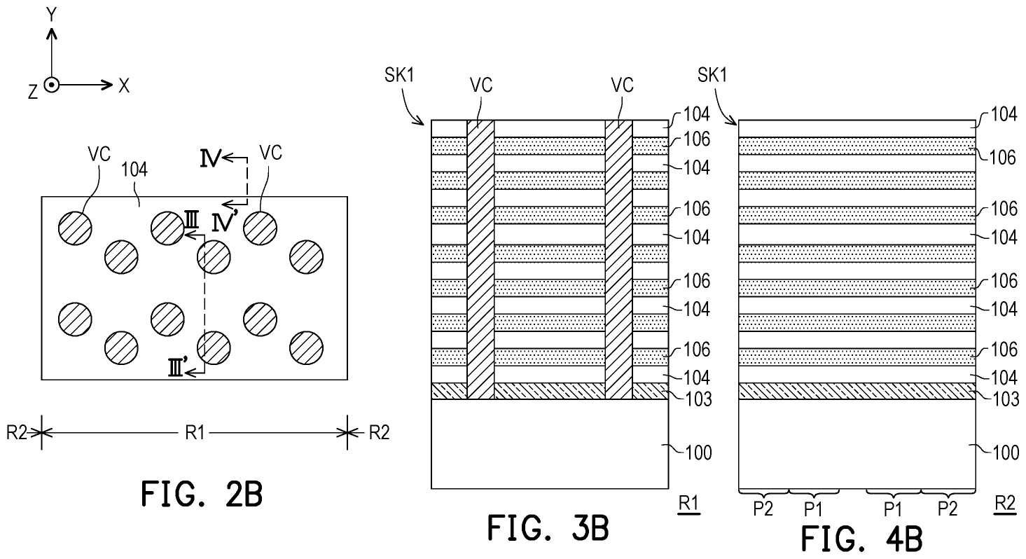

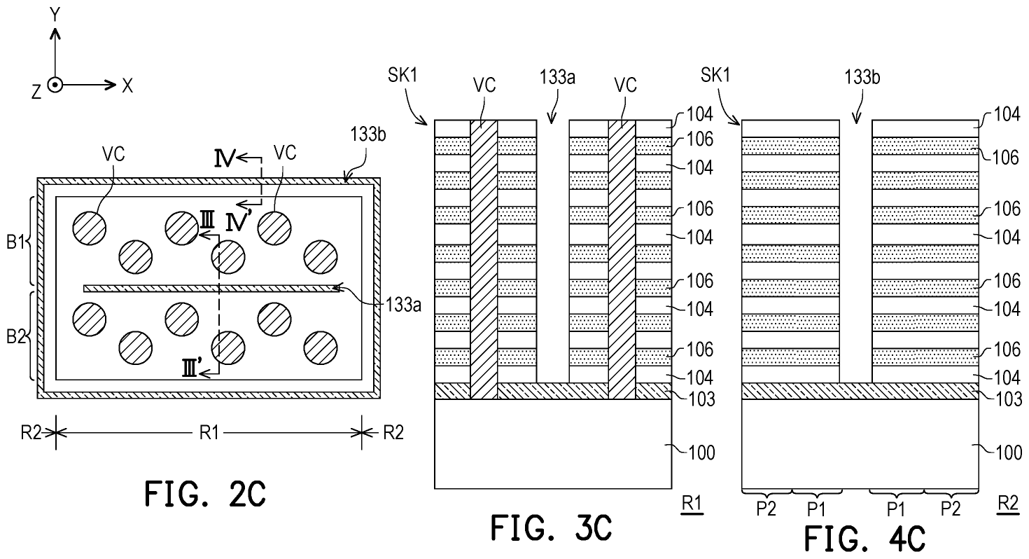

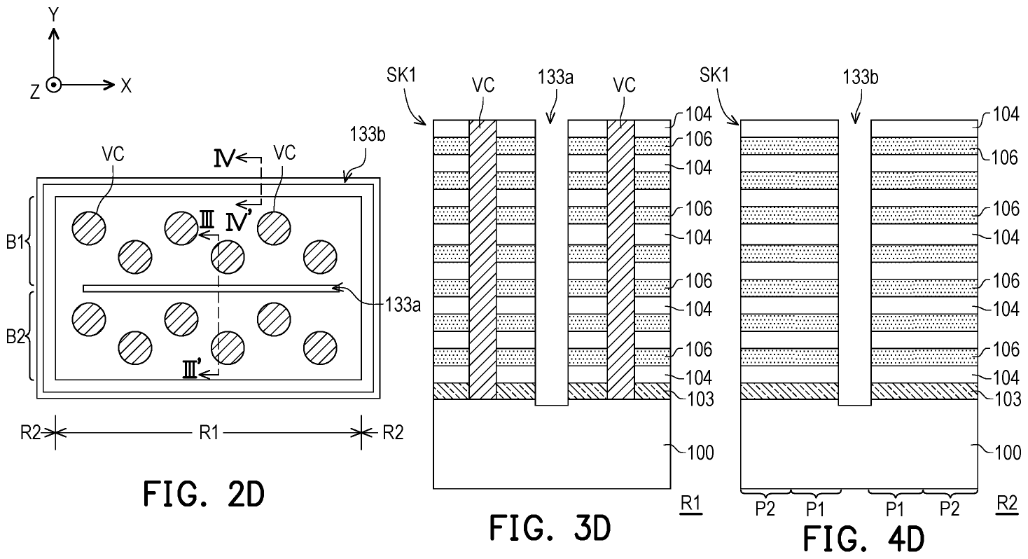

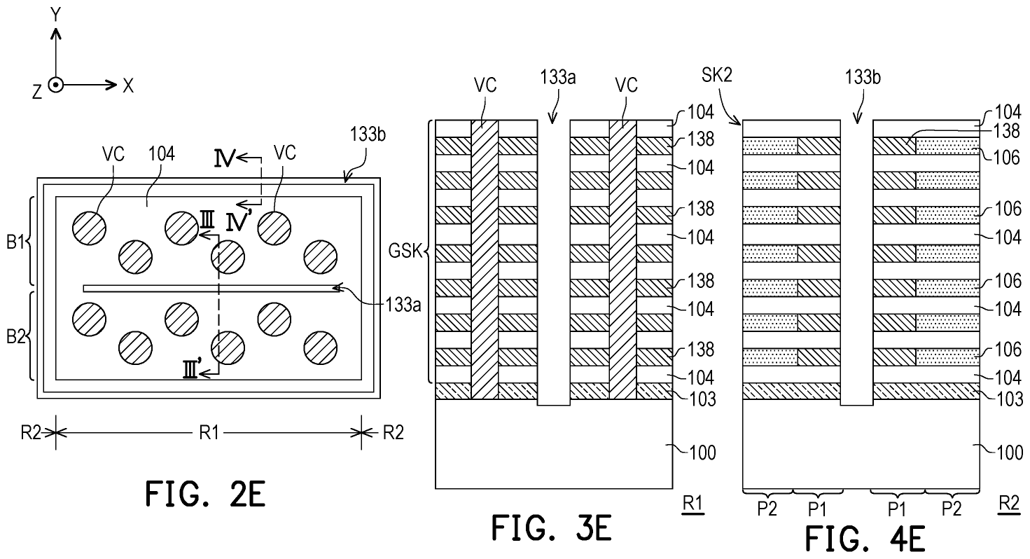

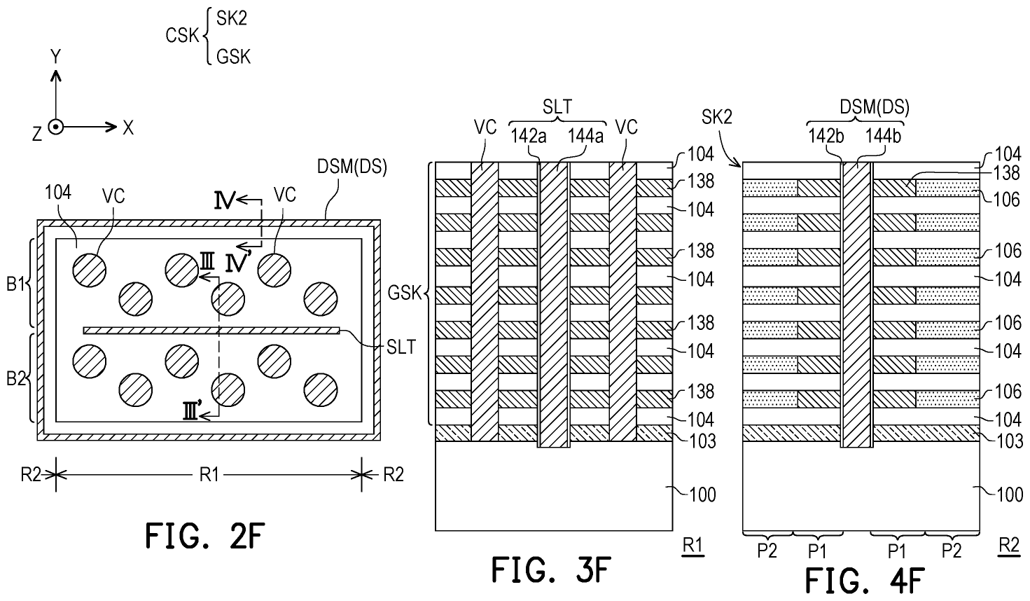

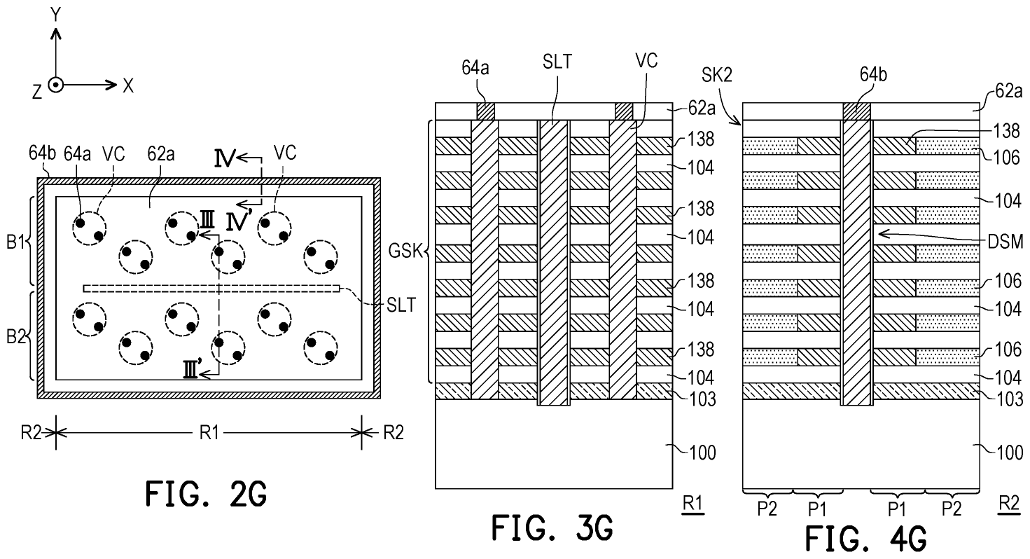

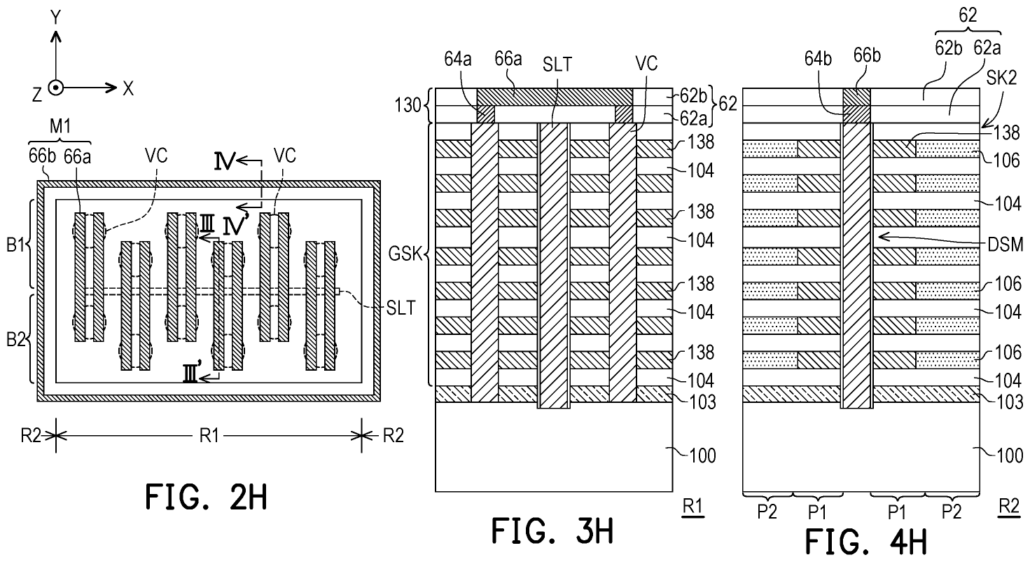

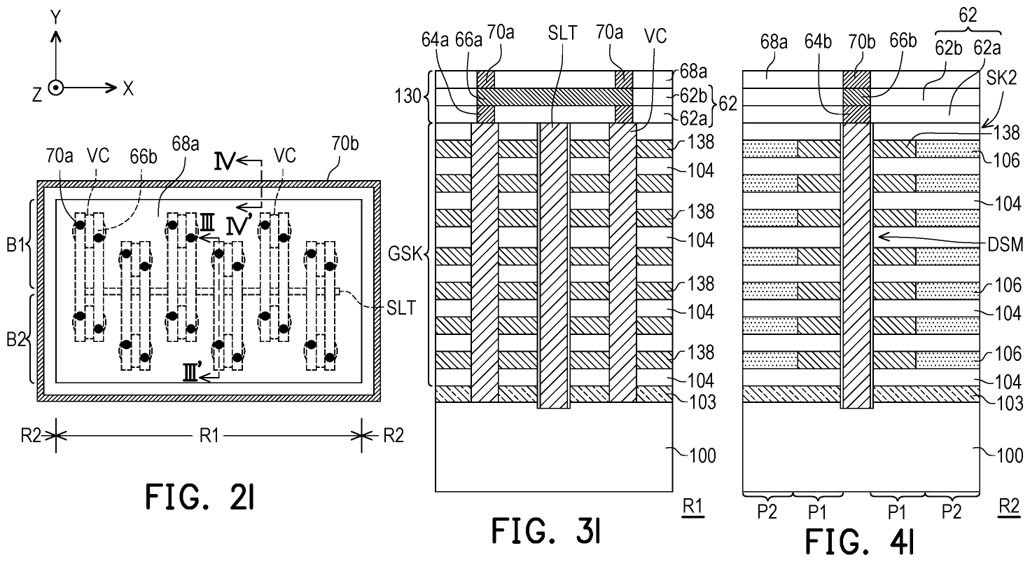

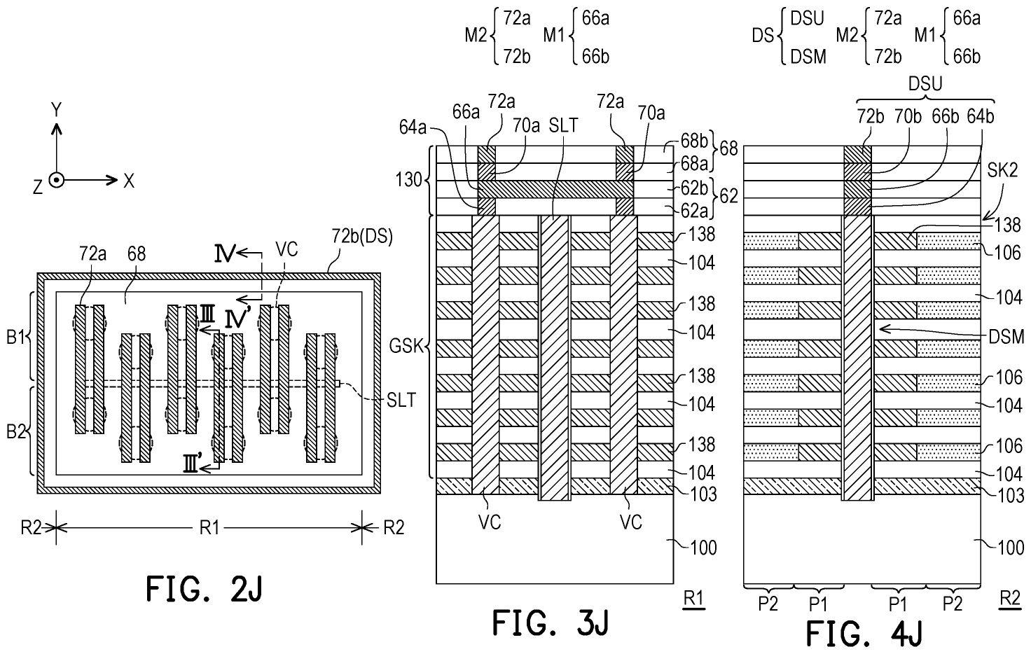

Referring to 1F, in some embodiments of the disclosure, the stack structure in the first region R1 of a first tile region T1 or a second tile region T2 is divided into a plurality of blocks (e.g., B1 and B2) by at least a slit structure SLT. While forming the slit structure SLT, a middle section DSM of a seal ring DS is also formed in the stack structure SK1 in the second region (such as the peripheral region) R2. The formation methods of the slit structure SLT and the middle section DSM of the seal ring DS may be referred to as shown in FIG. 2A to FIG. 2J, FIG. 3A to FIG. 3J, and FIG. 4A to FIG. 4J.

FIG. 2A to FIG. 2J illustrate top views of a manufacturing flow of a 3D AND flash memory according to some embodiments. FIG. 3A to FIG. 3J are cross-sectional views of line III-III′ of FIG. 2A to FIG. 2J. FIG. 4A to FIG. 4J are cross-sectional views of line IV-IV′ of FIG. 2A to FIG. 2J. Also, some layers or components are not shown in FIG. 2A to FIG. 2J, FIG. 3A to FIG. 3J, and FIG. 4A to FIG. 4J for clarity.

Referring to FIG. 2A, FIG. 3A and FIG. 4A, a dielectric substrate 100 is provided. The dielectric substrate 100 is, for example, a dielectric layer on a lower interconnect structure formed on the silicon substrate, such as a silicon oxide layer. The dielectric substrate 100 includes a first region R1 and a second region R2 surrounding the first region R1. The first region R1 may also be referred to as a tile region, and the second region R2 may also be referred to as a peripheral region. A stack structure SK1 is formed on the dielectric substrate 100 in the first region R1 and the second region R2. The stack structure SK1 may also be referred to as an insulating stack structure SK1.

In the present embodiment, the stacked structure SK1 includes a plurality of insulating layer 104 and a plurality of intermediate layer 106 stacked on the dielectric substrate 100 in sequence. In other embodiments, the stacked structure SK1 may include the intermediate layer 106 and the insulating layer 104 stacked on the dielectric substrate 100 in sequence. The insulating layer 106 is, for example, silicon oxide, and the intermediate layer 106 is, for example, silicon nitride. The intermediate layer 106 may be used as a sacrificial layer, which may be completely or partially removed in a subsequent process. In this embodiment, the stack structure SK1 has eight insulating layers 104 and seven intermediate layers 106, but the disclosure is not limited thereto. In other embodiments, more layers of the insulating layer 104 and more layers of the intermediate layer 106 may be formed according to actual needs.

In some embodiments, before the stack structure SK1 is formed, a conductive layer 103 are formed on the dielectric substrate 100 first. The conductive layer 103 is, for example, a grounded polysilicon layer. The conductive layer 103 may also be referred to as a dummy gate, which may be used to close the leakage path.

The stack structure SK1 was patterned to form a staircase structure (not shown) in a staircase region (not shown) in the first region R1.

Next, referring to FIG. 2B, FIG. 3B and FIG. 4B, a plurality of pillar structure VC are formed in the stack structure SK1 in the first region R1. In some embodiments, each pillar structure VC may include a channel pillar 16, the first conductive pillar 32a, the second conductive pillar 32b, the tunneling layer 14 and the charge storage layer 12 of the charge storage structure 40, the insulating pillar 28, and the insulating filling layer 24 shown in FIG. 1C. In other embodiments, each pillar structure VC may include the channel pillar 16, the first conductive pillar 32a, the second conductive pillar 32b, the insulating pillar 28, and the insulating filling layer 24 shown in FIG. 1D. For the sake of brevity, only the pillar structure VC is represented, and the detailed components of the pillar structure VC are not shown. The channel pillar 16, the first conductive pillar 32a, the second conductive pillar 32b, the tunneling layer 14 and the charge storage layer 12 of the charge storage structure 40, the insulating pillar 28 and the insulating filling layer 24 may be formed by any method, and are not described herein in detail.

FIG. 2C to FIG. 2E, FIG. 3C to FIG. 3E, and FIG. 4C to FIG. 4E, a replacement process is performed to replace the plurality of intermediate layers 106 with a plurality of gate layer 138. First, referring to FIG. 2C, FIG. 3C and FIG. 4C, a patterning process (i.e., lithography and etching processes) is performed on the stack structure SK1 to form trenches 133a and 133b in the first region R1 and the second region R2 respectively. During the etching process, the conductive layer 103 may be used as an etching stop layer, so that the trench 133 exposes the conductive layer 103.

Referring to FIG. 2C, from the top view, the trench 133a extends along the X direction, so that the stack structure SK1 in the first region R1 is divided into a plurality of blocks B1 and B2. From the top view, the trench 133b has a ring profile and surrounds the first region R1. The trench 133b is separated from the first region R1 by a non-zero distance.

Next, referring to FIG. 2D, FIG. 3D and FIG. 4D, the etching process is continued to remove the exposed conductive layer 103 by the trenches 133a and 133b, so that the trenches 133a and 133b extend through the conductive layer 103. The bottoms of the trenches 133a and 133b may expose the dielectric substrate 100.

After that, referring to FIG. 2E, FIG. 3E and FIG. 4E, an etching process, such as a wet etching process, is performed to remove a portion of the plurality of intermediate layers 106. Since the etchant used in the etching process (e.g., hot phosphoric acid) is injected into the trenches 133a and 133b, the portion of the plurality of intermediate layer 106 which contact the etchant is removed. Through the control of the time mode, the portion of the plurality of intermediate layer 106, which is near the trenches 133a and 133b, may be removed to form a plurality of horizontal openings (not shown). The other portion of the plurality of intermediate layer 106, which is farther from the trenches 133a and 133b, is left.

Referring to FIGS. 2E, 3E and 4E, in some embodiments, the gate layer 138 and the blocking layer (not shown) of the charge storage structure are formed in a plurality of horizontal openings. The blocking layer may be the blocking layer 36 shown in FIG. 1C. In other embodiments, besides the gate layer 138, a tunneling layer (not shown), a charge storage layer (not shown) and a blocking layer (not shown) of the charge storage structure are also formed. The tunneling layer, the charge storage layer and the blocking layer may be the tunneling layer 14, the charge storage layer 12 and the blocking layer 36 shown in FIG. 1D. The method for forming the gate layer 138 is, for example, to fill the trenches 133a and 133b and a plurality of horizontal openings (not shown) with conductive material, and then perform an etching back process to remove the conductive material in the trenches 133a and 133b.

Referring to FIG. 3E and FIG. 4E, the intermediate layer 106, the plurality of gate layer 138 and the plurality of insulating layer 104 which are not removed form a stack structure SK2. Referring to FIG. 3E, the plurality of intermediate layer 106 around the trench 133a are replaced by a plurality of gate layer 138. The plurality of gate layer 138 and the plurality of insulating layer 104 form a gate stack structure GSK. memory cell may be formed where the gate layer 138 intersects with the pillar structure VC. Therefore, a plurality of memory cells are included in the gate stack structure GSK. The stack structure SK2 and the gate stack structure GSK form a composite stack structure CSK.

Referring to FIG. 4E, the intermediate layer 106 around the trench 133b is replaced by a gate layer 138. The plurality of intermediate layer 106 away from the trench 133b are left. In the second region R2, the plurality of gate layers 138 and the plurality of insulating layers 104 are alternately stacked with each other to form the first portion P1 of the stack structure SK2. In the second region R2, the remaining intermediate layers 106 and the insulating layers 104 are alternately stacked with each other to form the second portion P2 of the stack structure SK2.

Referring to FIGS. 2F, 3F and 4F, a slit structure SLT and a middle section DSM of the seal ring DS are formed in the trenches 133a and 133b respectively. The gate stack structure GSK is divided into a plurality of blocks B1 and B2 by the slit structure SLT. The middle section DSM of the seal ring DS is surrounded by and in contact with the first portion P1 of the stack structure SK2.

In some embodiments, the slit structure SLT may include a liner layer 142a and a body part 144a. The middle section DSM of the seal ring DS may include a liner layer 142b and a body part 144b. The body parts 144a and 144b may provide support to avoid bending of the slit structure SLT. The liner layers 142a and 142b include an insulating material such as silicon oxide. The body parts 144a and 144b include a conductive material such as polysilicon. The formation method of the slit structure SLT and the middle section DSM of the seal ring DS includes the following step. The liner material and the body material are formed on the stack structure SK2 and filled in the trenches 133a and 133b. The excess liner material and the excess body material on the stack structure SK2 are removed through the etching back process or the planarization process. The liner layer 142a may electrically isolate the gate layer 138 from the body part 144a. The liner layer 142b may electrically isolate the gate layer 138 from the body part 144b, block moisture and reduce the stress of the body portion 144b.

Referring to FIG. 2J, FIG. 3J, and FIG. 4J, an upper interconnect structure (or referred to as a first interconnect structure) 130 is formed on the stack structure SK2. The upper interconnect structure 130 includes source lines, bit lines, and an upper section DSU. The source lines and the bit lines connect the pillar structures VC (e.g., the first conductive pillars 32a and the second conductive pillars 32b shown in FIG. 1C or FIG. 1D) respectively. The upper section DSU connects the seal ring DS of the middle section DSM of the seal ring DS. More specifically, the upper interconnect structure 130 includes dielectric layers 62 and 68, a plurality of plugs 64a, 64b, a first conductive layer M1 (including a plurality of conductive lines 66a, 66b), a plurality of vias 70a and 70b, and a second conductive layer M2 (including a plurality of conductive lines 72a, 72b). The plurality of conductive lines 66a may be used as the source lines and the bit lines, and are electrically connected to the pillar structure VC (e.g., the first conductive pillars 32a and the second conductive pillars 32b shown in FIG. 1C or FIG. 1D) through plugs 64a. The plugs 64b, the conductive lines 66b of the first conductive layer M1, the vias 70b and the conductive lines 72b of the second conductive layer M2 may together form the upper section DSU of the seal ring DS, and may be electrically connected to the lower middle section DSM of the seal ring DS. The components and forming methods of the upper interconnect structure 130 are described in detail as follows.

Referring to FIG. 2G, FIG. 3G and FIG. 4G, a dielectric layer 62a and plugs 64a and 64b are formed on the stack structure SK2 in the first region R1 and the second region R2. The plugs 64a and 64b are buried in the dielectric layer 62a. The plugs 64a lands on and electrically connected to the first conductive pillar 32a and the second conductive pillar 32b in the first region R1. The plug 64b lands on the middle section DSM of the seal ring DS in the second region R2. In some embodiment, from a top view, the plug 64a has an island-like or dot-like profile, and the plug 64b has annular profile, as shown in FIG. 2G. The size (diameter length) of the plug 64a may be smaller than or equal to the size of the first conductive pillar 32a and the second conductive pillar 32b shown in FIG. 1C or FIG. 1D. The size (line width) of the plug (or referred to as a first plug) 64b may be greater than, equal to or smaller than the size (line width) of the middle section DSM of the seal ring DS.

Referring to FIGS. 2H, 3H and 4H, a dielectric layer 62b and a first conductive layer M1 are formed on the dielectric layer 62a. The first conductive layer M1 is buried in the dielectric layer 62b. The first conductive layer M1 refers to the first conductive layer of the upper interconnect structure 130 above the stack structure SK2. The first conductive layer M1 includes a plurality of conductive lines 66a and 66b. The conductive lines 66a and 66b are electrically connected to the plugs 64a and 64b, respectively. In some embodiments, the plurality of conductive lines 66a of the second conductive layer M2 may be used as the source lines and the bit lines. From the top view, the shape of the conductive line 66a includes a straight line or a bend line (not shown). The conductive line (or referred to as a first conductive line) 66b has an annual profile. The size (line width) of the conductive line 66a may be smaller than or equal to the size of the underlying plug 64a. The size (line width) of the conductive line 66b may be greater than, equal to or smaller than the size (line width) of the underlying plug 64b.

FIG. 3H and FIG. 4H, the plugs 64a and 64b and the plurality of conductive lines 66a and 66b are, for example, metal such as tungsten or copper. In some embodiments, the plugs 64a and 64b further include a barrier layer between the metal layer and the dielectric layer 62a, and between the metal layer and the dielectric layer 62b. The barrier layer is, for example, titanium, titanium nitride, tantalum, tantalum nitride or a combination thereof. The plugs 64a and 64b and the plurality of conductive lines 66a and 66b may be formed through a single damascene or dual metal damascene process, but are not limited thereto. The following is a description of the dual metal damascene process.

FIG. 3H and FIG. 4H, a dielectric layer 62 is formed on the stack structure 52 and stack structure SK2. The dielectric layer 62 includes dielectric layers 62a and 62b. The dielectric layers 62a and 62b may have an interface or no interface therebetween. The dielectric layer 62 is silicon oxide, for example. A plurality of trenches (not shown) and a plurality of plug holes (not shown) are formed in the dielectric layer 62 through lithography and etching processes. After that, the barrier layer and a metal filling layer are refilled in the plurality of trenches (not shown) and a plurality of plug holes. Then, the excess barrier layer and the excess metal filling layer on the dielectric layer 62 are removed through an etching back process or a chemical mechanical polishing process to form the plugs 64a and 64b and the plurality of conductive lines 66a and 66b.

FIG. 21, FIG. 3I and FIG. 3I, a dielectric layer 68a and a plurality of vias 70a and 70b are formed on the dielectric layer 62 and the plurality of conductive lines 66a and 66b. The plurality of vias 70a and 70b are buried in the dielectric layer 68a. The vias 70a land on and are electrically connected to the conductive line 66a. The via 70b lands on and is electrically connected to conductive line 66b. From a top view, the via 70a has an island-like or dot-like profile, as shown in FIG. 21. The via 70b has annular profile. The dimension of via 70a may be less than or equal to the dimension of underlying conductive line 66a. The dimension (diameter) of via 70b may be greater than, equal to or smaller than the dimension (line width) of the plurality of conductive lines 66b.

Referring to FIG. 2J, FIG. 3J and FIG. 4J, a dielectric layer 68b and a second conductive layer M2 are formed on the dielectric layer 68a. The second conductive layer M2 is buried in the dielectric layer 68b. The second conductive layer M2 refers to the second conductive layer of the upper interconnect structure 130 above the stack structure SK2. The second conductive layer M2 includes a plurality of conductive lines 72a and 72b. The conductive lines 72a and 72b each extend along direction Y and are arranged along direction X, respectively. The conductive lines 72a and 72b are electrically connected to the vias 70a and 70b, respectively. In the Z direction, the conductive lines 72a and 72b overlap with the conductive lines 66a and 66b, respectively. The conductive lines 72b may be referred to as second conductive lines.

Referring to FIG. 3J and FIG. 4J, the vias 70a and 70b and the plurality of conductive lines 72a and 72b are metal filling layers, such as tungsten or copper, for example. In some embodiments, vias 70a and 70b further include a barrier layer between the metal filling layer and the dielectric layers 68a and 68b. The barrier layer is, for example, titanium, titanium nitride, tantalum, tantalum nitride or a combination thereof. The vias 70a and 70b and the plurality of conductive lines 72a and 72b may be formed through a single damascene or dual metal damascene process, but are not limited thereto. The following is a description of the dual metal damascene process.

Referring to FIG. 3J, first, a dielectric layer 68 is formed on the dielectric layer 62 and the first conductive layer M1. The dielectric layer 68 includes dielectric layers 68a and 68b. The dielectric layers 68a and 68b may have an interface or no interface therebetween. The dielectric layer 68 is silicon oxide, for example. In some embodiments, a plurality of trenches and a plurality of plug holes are formed in the dielectric layer 68 through a patterning process (i.e., lithography and etching processes). In other embodiments, the plurality of trenches (not shown) and the plurality of plug holes (not shown) may be formed through a self-aligned double patterning (SADP) process. After that, the barrier layer and metal filling layer are refilled. Then, the excess barrier layer and metal filling layer on the dielectric layer 68 are removed through an etching back process or a chemical mechanical polishing process to form vias 70a and 70b and a plurality of conductive lines 72a and 72b.

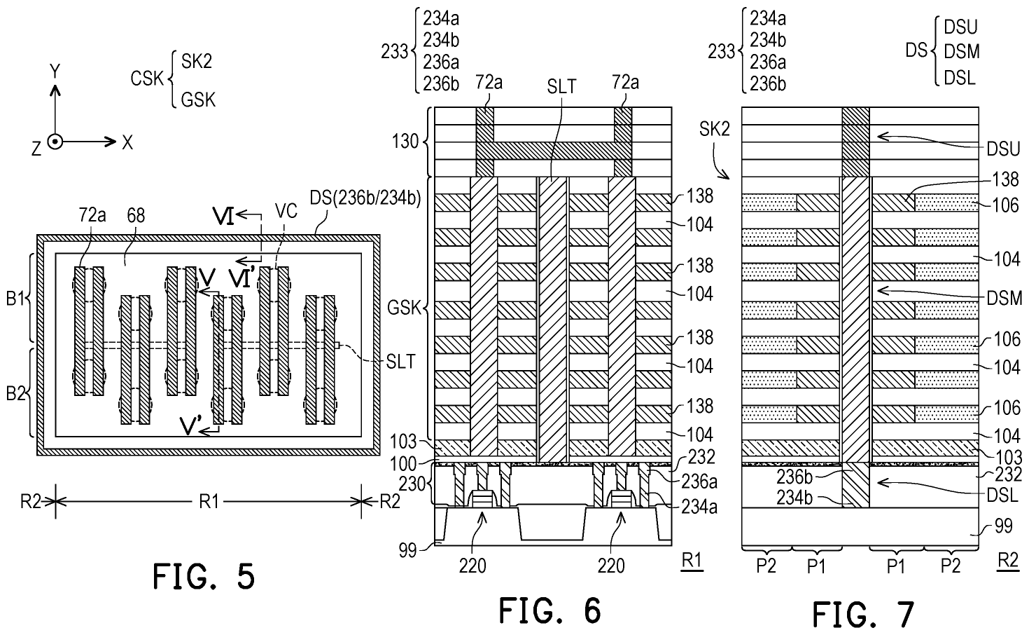

FIG. 5 shows a top view of a 3D AND flash memory according to other embodiments. FIG. 6 shows a cross-sectional view along line V-V′ of FIG. 5. FIG. 7 shows a cross-sectional view along line VI-VI′ of FIG. 5.

Referring to FIG. 5, FIG. 6 and FIG. 7, in other embodiments, a circuit structure 220 and a lower interconnect structure (or referred to as a second interconnect structure) 230 are further formed between a substrate 99 and the stack structure SK2. The dielectric substrate 100 is located between the conductive layer 103 and the substrate 99. The substrate 99 includes, for example, a semiconductor substrate. The circuit structure 220 may include an active device or a passive device. The active device such as a transistor, a diode and so on. The Passive device such as a capacitor, an inductor and so on. The transistor may be an N-type metal oxide semiconductor (NMOS) transistor, a P-type metal oxide semiconductor (PMOS) transistor or a complementary metal oxide semiconductor element (CMOS). In some embodiments, circuit structure 20 may include a plane-buffer.

Referring to FIG. 5, FIG. 6 and FIG. 7, the lower interconnect structure 30 may include a plurality of dielectric layer 232 and a conductive interconnect 233 formed in the plurality of dielectric layer 232. The conductive interconnect 233 includes a plurality of plugs 234a and 234b, a plurality of conductive lines 236a and 236b, and the like. The conductive line 236a may be connected to the circuit structure 220 through the plug 234a. The conductive line (or referred to as a third conductive line) 236b and the plug (or referred to as a second plug) 234b may together form a lower section DSL of the upper section DSL of the seal ring DS to electrically connect the middle section DSM of the seal ring DS. From the top view, the conductive line 236b and the plug 234b have annular profile, for example. The size (diameter) of the conductive line 236b and the plug 234b may be greater than, equal to or smaller than the size (line width) of the middle section DSM of the seal ring DS.

Based on the above, in the three-dimensional flash memory of an embodiment of the disclosure, the seal ring of an embodiment of the disclosure may pass through the ground conductor layer upward from the surface of the substrate, and be continuously extended to the top surface of the upper interconnect structure. Therefore, the three-dimensional flash memory of an embodiment of the disclosure may effectively isolate the stacked structure of two adjacent tile regions to reduce or avoid the leakage path between the substrate and the ground conductor layer and increase the off current Ioff, and reduce impact on memory cell operations.

The manufacturing method of a three-dimensional flash memory of an embodiment of the disclosure may form a seal ring at the periphery of the block region while forming a memory element, and therefore the method may be integrated with the existing process without increasing the process steps.

What is claimed is:

1. A memory device, comprising:
a dielectric substrate having a first region and a second region surrounding the first region;
a composite stack structure, on the dielectric substrate in the first region and the second region;
a plurality of memory cells, in the composite stack structure;
a slit structure extending through the composite stack structure in first region, wherein the composite stack structure is divided into a plurality of blocks; and
a middle section of a seal ring extending through the composite stack structure in the second region, wherein the middle section of the seal ring comprises:
a body part extending through the composite stack structure in the second region; and
a liner layer located between the body part and the composite stack structure.

2. The memory device of claim 1, wherein the body part of the seal ring and the composite stack structure are electrically isolated by the liner layer of the seal ring.

3. The memory device of claim 1, wherein the liner layer of the seal ring comprises an insulating material, and the body part includes a conductive material.

4. The memory device of claim 1, further comprising:
a conductive layer, located between the composite stack structure and the dielectric substrate, wherein the middle section of the seal ring extends through the conductive layer.

5. The memory device of claim 4, wherein the seal ring further comprises:
a lower section, disposed below and connected to the middle section, wherein the lower section is a portion of a first interconnect, wherein the first interconnect is located between the dielectric substrate and a substrate; and
an upper section disposed on and connected to the middle section, wherein the upper section is a portion of a second interconnect, and the second interconnect is located above the composite stack structure.

6. A method of manufacturing a flash memory device, comprising:
providing a dielectric substrate, wherein the dielectric substrate has a first region and a second region surrounding the first region;
forming a stack structure on the dielectric substrate in the first region and the second region, wherein the stack structure comprises a plurality of insulating layers and a plurality of intermediate layers alternately stacked each other; and
forming a slit structure and a middle section of a seal ring, wherein the slit structure is located in the stack structure in the first region, and the middle section of the seal ring is located in the stack structure in the second region.

7. The method of claim 6, wherein forming the slit structure and the seal ring comprises:
forming a first trench and a second trench, wherein the first trench is located in the stack structure in the first region, and the second trench is located in the stack structure in the second region;
forming a first liner layer and a second liner layer, wherein the first liner layer is located on sidewalls of the first trench, and the second liner layer is located on sidewalls of the second trench; and
forming a first body part and a second body part, wherein the first body part is located in a remaining space of the first trench, and the second body part is located in a remaining space of the second trench.

8. The method of claim 7, further comprising:
before forming the first liner layer and the second liner layer, replacing the plurality of intermediate layers surrounding the first trench and the second trench with a plurality of gate layers.

9. The method of claim 8, further comprising:
forming a conductive layer between the stack structure and the dielectric substrate, wherein the first trench and the second trench further extend through the conductive layer.

10. The method of claim 6, further comprising:
forming a first interconnect between the dielectric substrate and a substrate, wherein a portion of the first interconnect forms a lower section of the seal ring; and
forming a second interconnect above the stack structure, a portion of the second interconnect forms an upper section of the seal ring.

11. A semiconductor device, comprising:
a composite stack structure on a dielectric substrate, wherein the composite stack structure comprises a plurality of conductive layers and a plurality of insulating layers stacked alternately;
a seal ring, comprising:
a middle section extending through the composite stack structure and electrically isolated from the plurality of conductive layers;
an upper section located above and electrically connected to the middle section; and
a lower section located below and electrically connected to the middle section.

12. The semiconductor device of claim 11, w herein the middle section of the seal ring comprises:
a body part extending through the composite stack structure; and
a liner layer located between the body part and the composite stack structure.

13. The semiconductor device according to claim 12, wherein the body part and the liner layer have a ring profile.

14. The semiconductor device according to claim 11, wherein the upper section comprises:
a first plug located on the body part and electrically connected to the body part;
a first conductive line located on the first plug and electrically connected to the first plug;
a via located on the first conductive line and electrically connected to the first conductive line; and
a second conductive line located on the via and electrically connected to the via.

15. The semiconductor device according to claim 14, wherein the first plug, the first conductive line, the via and the second conductive line have a ring profile.

16. The semiconductor device of claim 11, wherein the lower section comprises:
a third conductive line located under the body part and electrically connected to the body part; and
a second plug located under the third conductive line and electrically connected to the third conductive line.

17. The semiconductor device of claim 16, wherein the third conductive line and the second plug have a ring profile.
